(19) United States
(12) Patent Application Publication
(10) Pub. No.: US 2025/0379127 A1
(43) Pub. Date: Dec. 11, 2025

(54) LEAD FRAME STRIP, METHOD OF MAKING THE SAME, AND SEMICONDUCTOR DEVICE

(71) Applicant: SHINKO ELECTRIC INDUSTRIES CO., LTD., Nagano (JP)

(72) Inventors: Kentaro KANEKO, Nagano (JP); Konosuke KOBAYASHI, Nagano (JP); Kenichi KOMATSU, Nagano (JP); Takuya MIYAZAWA, Nagano (JP)

(21) Appl. No.: 19/227,907

(22) Filed: Jun. 4, 2025

(30) Foreign Application Priority Data
Jun. 11, 2024 (JP) 2024-094336

(51) Int. Cl. H01L 23/495; H01L 23/00; H01L 23/31

(52) U.S. Cl. CPC H01L 23/49548; H01L 23/3107; H01L 24/48; H01L 2224/48245

(57) ABSTRACT

A lead frame strip includes a frame portion and a plurality of leads projecting from an inner edge of the frame portion to an inside of the frame portion, wherein each of the leads has a lower surface, an upper surface opposite the lower surface, and a step surface recessed relative to the upper surface toward the lower surface, and wherein the step surface is convex upward in a vertical cross-section that is taken through the step surface perpendicularly to a direction in which the leads project.

### CROSS-REFERENCE TO RELATED APPLICATIONS

The present application is based on and claims priority to Japanese Patent Application No. 2024-094336 filed on Jun. 11, 2024, with the Japanese Patent Office, the entire contents of which are incorporated herein by reference.

### FIELD

The disclosures herein relate to lead frame strips, methods of making a lead frame strip, and semiconductor devices.

### BACKGROUND

A semiconductor device as known in the art includes a semiconductor chip mounted on a lead frame. In manufacturing such a semiconductor device, a plurality of semiconductor chips are mounted on a lead frame strip to prepare a plurality of regions that will become respective semiconductor devices, and, thereafter, cuts are performed at predetermined positions to obtain singulated semiconductor devices.

At the time of cutting, leads arranged side by side in the lead frame strip may be cut. Such cutting may result in formation of burrs. Presence of burrs in a lead gives rise to a possibility that adjacent leads, which normally electrically isolated from each other, may be short-circuited due to burrs.

There may be a need to provide a lead frame strip having a structure that is unlikely to cause a short circuit between adjacent leads.

### PRIOR ART DOCUMENTS

### Patent Documents

[Patent Documents 1] Japanese Laid-Open Patent Publication No. 2001-77279

### SUMMARY

According to an aspect of the embodiment, a lead frame strip includes a frame portion and a plurality of leads projecting from an inner edge of the frame portion to an inside of the frame portion, wherein each of the leads has a lower surface, an upper surface opposite the lower surface, and a step surface recessed relative to the upper surface toward the lower surface, and wherein the step surface is convex upward in a vertical cross-section that is taken through the step surface perpendicularly to a direction in which the leads project.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a top view illustrating an example of an entire lead frame strip according to a first embodiment;

FIGS. 2A and 2B are top views illustrating an example of a distinct region and its surrounding area of the lead frame strip according to the first embodiment;

FIG. 3 is a bottom view illustrating the example of the distinct region and its surrounding area of the lead frame strip according to the first embodiment;

FIGS. 4A through 4C are cross-sectional views illustrating the example of the distinct region and its surrounding area of the lead frame strip according to the first embodiment;

FIGS. 5A through 5C are drawings (part 1) illustrating an example of the manufacturing process of the lead frame strip according to the first embodiment;

FIGS. 6A through 6C are drawings (part 2) illustrating the example of the manufacturing process of the lead frame strip according to the first embodiment;

FIGS. 7A through 7C are drawings (part 3) illustrating the example of the manufacturing process of the lead frame strip according to the first embodiment;

FIGS. 8A and 8B are drawings illustrating an example of a semiconductor device according to a second embodiment;

FIGS. 9A through 9C are drawings illustrating an example of the manufacturing process of the semiconductor device according to the second embodiment;

FIGS. 10A through 10C are drawings illustrating examples of a lead frame and a semiconductor device according to a first variation;

FIGS. 11A and 11B are top views illustrating an example of a distinct region and its surrounding area of a lead frame strip according to a second variation;

FIGS. 12A through 12C are cross-sectional views illustrating the example of the distinct region and its surrounding area of the lead frame strip according to the second variation;

FIGS. 13A through 13C are top views illustrating a method of making the shape illustrated in FIG. 11B;

FIGS. 14A through 14C are bottom views illustrating the method of making the shape illustrated in FIG. 11B;

FIG. 15 is a top view illustrating side edges;

FIGS. 16A and 16B are top views illustrating an example of a distinct region and its surrounding area of a lead frame strip according to a third variation;

FIGS. 17A through 17C are cross-sectional views illustrating the example of the distinct region and its surrounding area of the lead frame strip according to the third variation;

FIGS. 18A through 18C are top views illustrating a method of making the shape illustrated in FIG. 16B; and

FIGS. 19A through 19C area bottom views illustrating the method of making the shape illustrated in FIG. 16B.

### DESCRIPTION OF EMBODIMENTS

In the following, embodiments for carrying out the invention will be described with reference to the accompanying drawings. In the drawings, the same components are referred to by the same reference numerals, and duplicate descriptions thereof may be omitted.

### First Embodiment

### [Lead Frame]

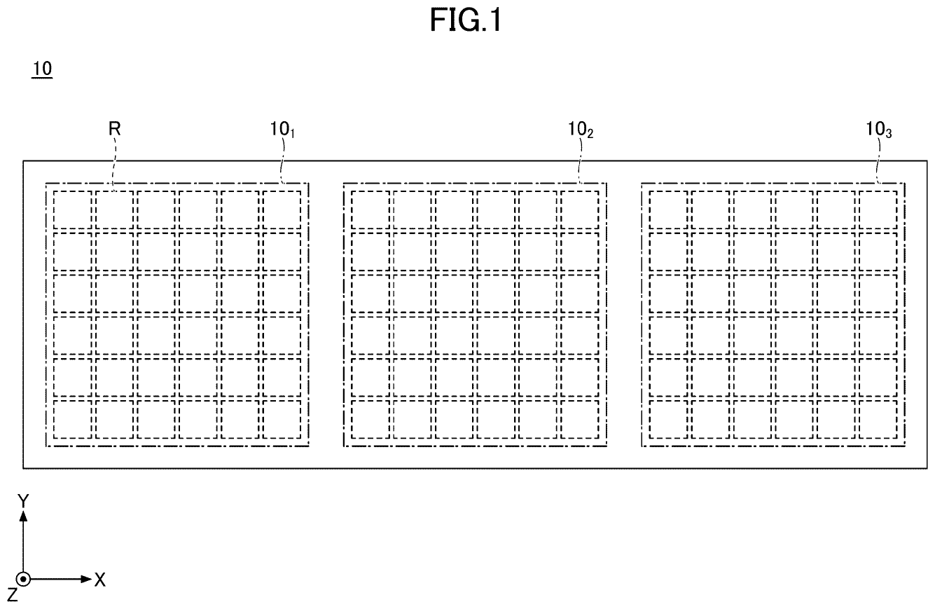

FIG. 1 is a top view illustrating an example of the entirety of a lead frame strip according to the first embodiment. In FIG. 1, the X, Y, and Z axes are orthogonal to each other. Referring to FIG. 1, a lead frame strip 10 is, for example, rectangular in top view. In the example of FIG. 1, the lead frame strip 10 has long sides extending in the X axis direction and short sides extending in the Y axis direction. The lead frame strip 10 may have a square or other shape in top view.

In the example of FIG. 1, three regions 10₁, 10₂, and 10₃ are defined in the lead frame strip 10 in the top view, and a plurality of distinct regions R are defined in each of the regions 10₁, 10₂, and 10₃. The distinct regions R are spaced from each other and arranged in one or two dimensional array, for example. The distinct regions R are ultimately cut for singulation, forming a part of the respective semiconductor devices. The lead frame strip 10 may have 1, 2, or 4 or more regions. The number of distinct regions R in each region may be determined as appropriate.

In FIG. 1, the distinct regions R are illustrated as a simplified rectangular shape, but the distinct regions R need not be rectangular, and may have a more complicated shape according to the shape of the semiconductor device. The material of the lead frame strip 10 may be, for example, copper (Cu), copper alloy, 42 alloy, or the like. The thickness of the lead frame strip 10 may be, for example, 10 μm or more and 200 μm or less.

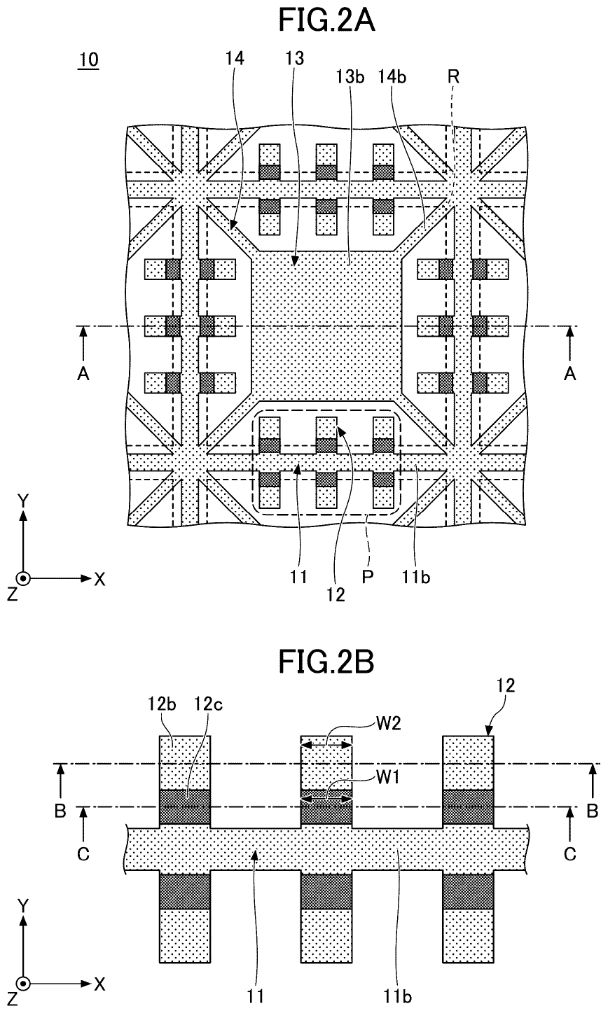

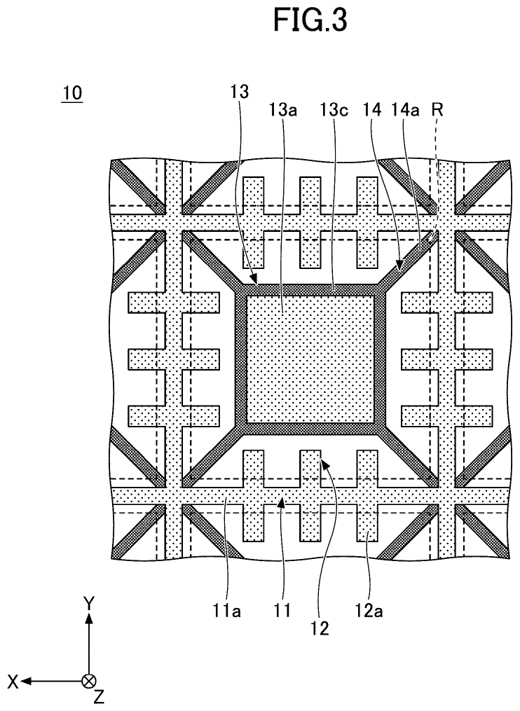

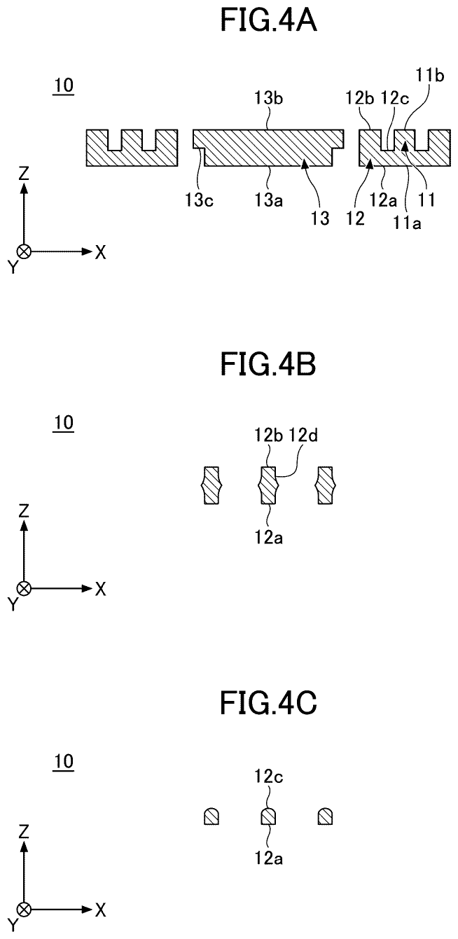

FIGS. 2A and 2B are top views illustrating an example of a distinct region and its surrounding area of the lead frame strip according to the first embodiment. FIG. 2A illustrates the entire distinct region, and FIG. 2B illustrates an enlarged view of a portion P illustrated in FIG. 2A. FIG. 3 is a bottom view illustrating an example of the distinct region and its surrounding area of the lead frame according to the first embodiment. FIGS. 4A through 4C are cross-sectional views illustrating an example of the distinct region and its surrounding area of the lead e f frame according to the first embodiment. FIG. 4A illustrates the cross-section along the line A-A in FIG. 2A. FIG. 4B illustrates the cross-section along the line B-B in FIG. 2B, and FIG. 4C illustrates the cross-section along the line C-C in FIG. 2B.

As illustrated in FIGS. 2A and 2B through FIGS. 4A to 4C, the lead frame strip 10 includes a frame portion 11, a plurality of leads 12, a die pad 13, and support bars 14 for each distinct region R and its surrounding area. For example, a plurality of elongated portions extending in the X-axis direction and a plurality of elongated portions extending in the Y-axis direction are arranged in a grid shape to form the frame portion 11. The frame portion 11 is arranged so as to surround each distinct region R in top view. The frame portion 11 may have a portion shared by one distinct region R and a distinct region R adjacent to that distinct region R. The width of the frame portion 11 may be, for example, approximately 0.1 to 0.2 mm.

The leads 12 project from the inner edge of the frame portion 11 to the inside of the frame portion 11. The leads 12 project perpendicularly to the inner edge of the frame portion 11, for example. The width of the leads 12 may be, for example, approximately 0.15 to 0.25 mm. The leads 12 are arranged apart from each other. Each of the leads 12 has a lower surface 12a, an upper surface 12b opposite the lower surface 12a, and a step surface 12c recessed relative to the upper surface 12b toward the lower surface 12a. The lower surface 12a and the upper surface 12b are parallel, for example. In the direction in which the frame portion 11 extends, the width of the step surface 12c is equal to the width of the upper surface 12b. The step surface 12c may be provided directly adjacent to the inner edge of the frame portion 11 on the lead 12. The step surface 12c may be provided between the portion of the lead 12 that is connected to a semiconductor chip (i.e., the portion connected to a metal wire 130 or a bonding member 125 described later) and the frame portion 11.

In the vertical cross-section taken through the step surfaces 12c and perpendicular to the direction in which the leads 12 project, that is, in the cross-section illustrated in FIG. 4C, the step surface 12c is convex upward, i.e., toward the plane of the upper surface 12b. In the cross-section illustrated in FIG. 4C, for example, the step surface 12c has a round shape in which the height is highest at the center in the X-axis direction and gradually decreases toward the periphery from the center in the X-axis direction.

In the vertical cross-section passing through the step surfaces 12c and parallel to the direction in which the leads 12 project, that is, in the cross-section illustrated in FIG. 4A, the step surface 12c is parallel to, for example, the lower surface 12a. In the Z-axis direction, the distance from the lower surface 12a to the highest point of the step surface 12c is about half the distance from the lower surface 12a to the upper surface 12b. In the cross-section illustrated in FIG. 4C, the side surface connecting the lower surface 12a and the step surface 12c may be a planar surface or a curved surface. When the side surface connecting the lower surface 12a and the step surface 12c is a planar surface, this planar surface may be perpendicular to the lower surface 12a or inclined.

In the vertical cross-section passing through the lower surfaces 12a and the upper surfaces 12b and perpendicular to the direction in which the leads 12 project, that is, in the cross-section illustrated in FIG. 4B, the side surface 12d connecting the lower surface 12a and the upper surface 12b bulges laterally outward at the center of the thickness (i.e., the center in the Z-axis direction), relative to the edges of the lower surface 12a and the upper surface 12b. The upper surface 11b of the frame portion 11 is flush with the upper surfaces 12b of the leads 12, and the lower surface 11a of the frame portion 11 is flush with the lower surfaces 12a of the leads 12. The width of the step surface 12c is narrower than the width of the portion of the lead 12 where the side surface 12d projects laterally outward at the center of the thickness (i.e., the center in the Z-axis direction).

The die pad 13 is disposed at the center of the distinct region R, apart from the leads 12. The die pad 13 is rectangular in top view, for example. The die pad 13 has, around the outer perimeter of the lower surface 13a, a second step surface 13c at a position recessed relative to the lower surface 13a toward the upper surface 13b. That is, the outer perimeter of the die pad 13 is thinner than the center area.

The support bars 14 connect the four corners of the die pad 13 to the four corners of the frame portion 11. That is, the die pad 13 is connected to the frame portion 11 and supported by the support bars 14. The support bars 14 is thinned similarly to the outer perimeter of the die pad 13. The upper surfaces 14b of the support bars 14 are flush with the upper surface 13b of the die pad 13, and the lower surfaces 14a of the support bars 14 are flush with the second step surface 13c of the die pad 13. The upper surfaces 14b of the support bars 14 are flush with the upper surface 11b of the frame portion 11. The lower surfaces 14a of the support bars 14 are positioned above the lower surface 11a of the frame portion 11.

### [Method of Making Lead Frame Strip]

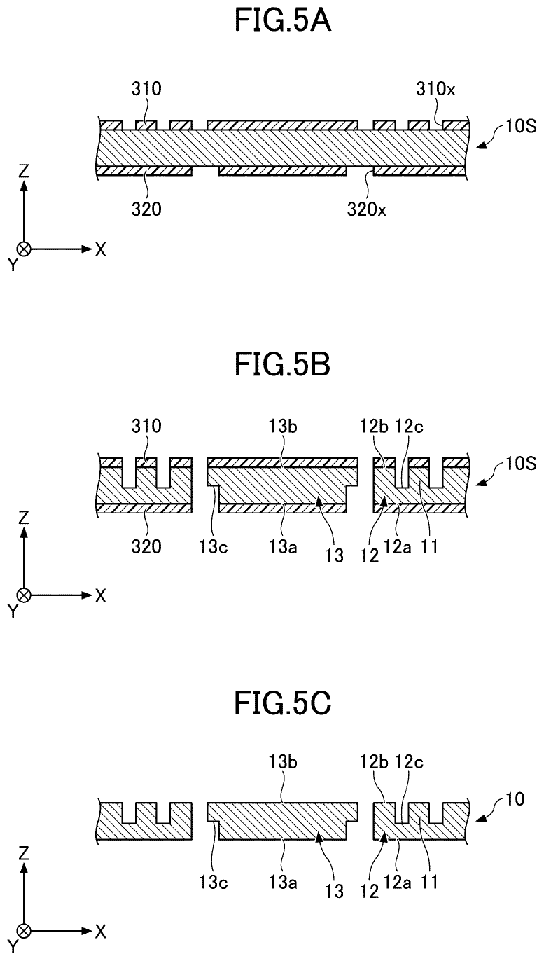

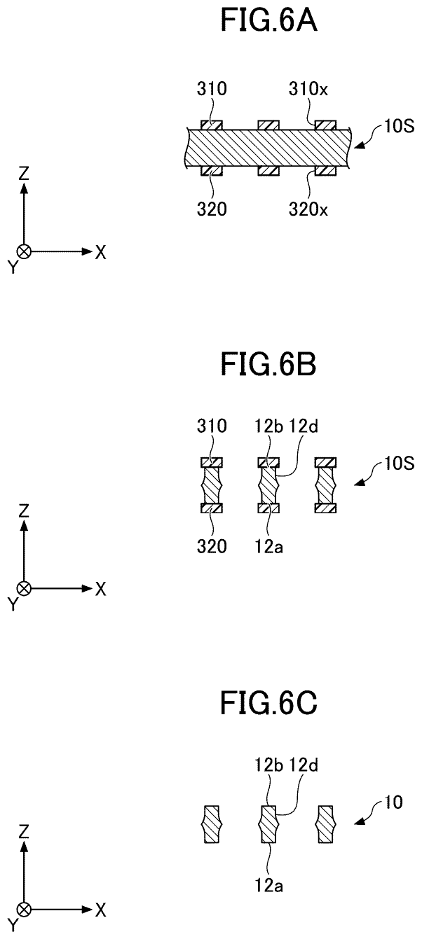

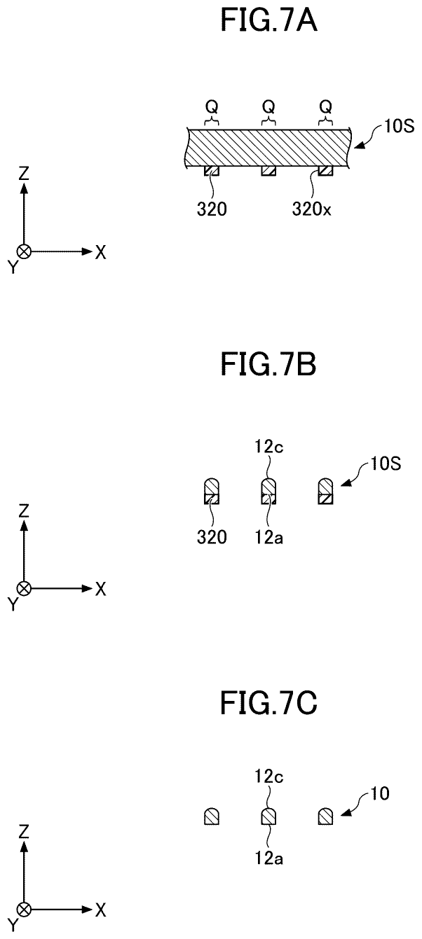

The following describes a method of making the lead frame strip according to the first embodiment. FIGS. 5A through 5C are a drawing illustrating an example of the manufacturing process of the lead frame strip according to the first embodiment, and each illustrate a cross-section corresponding to FIG. 4A. FIGS. 6A through 6C are drawings illustrating the example of the manufacturing process of the lead frame strip according to the first embodiment, and each illustrate a cross-section corresponding to FIG. 4B. FIGS. 7A through 7C are drawings illustrating the example of the manufacturing process of the lead frame strip according to the first embodiment, and each illustrate a cross-section corresponding to FIG. 4C. FIGS. 5A, 6A, and 7A illustrate the same step. Similarly, FIGS. 5B, 6B, and 7B illustrate the same step. FIGS. 5C, 6C, and 7C also illustrate the same step.

First, as illustrated in FIGS. 5A, 6A, and 7A, a metal plate 10S having a predetermined shape is prepared. Further, a resist layer 310 having openings 310x is disposed on the upper surface of the plate 10S, and a resist layer 320 having openings 320x is disposed on the lower surface. As illustrated in FIG. 1, for example, three regions 10₁, 10₂, and 10₃ are defined in the plate 10S in top view, and a plurality of distinct regions R are defined in each of the regions 10₁, 10₂, and 10₃. Here, one distinct region R and its surrounding area are illustrated.

The openings 310x and 320x are arranged according to the shape of the lead frame strip 10 to be formed. For example, at the position illustrated in FIG. 5A, the openings 310x and 320x include overlapping portions and non-overlapping portions in plan view. At the position illustrated in FIG. 6A, the openings 310x and 320x completely overlap in plan view. At the positions of regions Q illustrated in FIG. 7A, the resist layer 310 is not disposed, and only the resist layer 320 having the openings 320x is disposed. That is, the regions Q are where the resist layer 310 is not disposed, but only the resist layer 320 is disposed in plan view. Although not illustrated, at the portions where the support bars 14 are to be formed, the upper surface of the plate 10S is covered with the resist layer 310, and the openings 320x are disposed on the lower surface.

Next, as illustrated in FIGS. 5B, 6B, and 7B, the lead frame strip 10 is formed by etching (e.g., wet etching) the plate 10S through the resist layers 310 and 320. As illustrated in FIGS. 2A and 2B through FIGS. 4A to 4C, the lead frame strip 10 includes the frame portion 11, the die pad 13, the support bars 14, and the leads 12, which project from the inner edges of the frame portion 11 toward the inside of the frame portion 11, and have the lower surface 12a, the upper surface 12b opposite the lower surface 12a, and the step surface 12c recessed relative to the upper surface 12b toward the lower surface 12a.

Due to etching, the plate 10S is penetrated at the portions where the openings 310x and 320x overlap in plan view. Since the etching proceeds isotopically, for example, the side surface 12d is formed that has a center portion along the thickness (i.e., center portion in the Z-axis direction) bulging laterally outward beyond the lower surface 12a and the upper surface 12b as illustrated in FIG. 6B. Further, in the regions Q where the resist layer 310 is not provided and only the resist layer 320 is provided in plan view, only the upper side of the plate 10S is half-etched, and as illustrated in FIG. 7B, the step surface 12c that is convex upward, i.e., toward the plane of the upper surface 12b is formed. In the regions where the openings 310x are not provided and the openings 320x are provided in plan view, only the lower side of the plate 10S is half-etched. For example, as illustrated in FIG. 5B, the second step surface 13c is formed.

The frame portion 11 is covered with the resist layers on its upper and lower surfaces, and, thus, are not half-etched. As a result, the frame portion 11 is not thinned and maintains the thickness of the plate 10S, which effectively increases the rigidity of the lead frame strip 10, thereby effectively suppressing deformation of the lead frame strip 10.

As illustrated in FIGS. 5C, 6C, and 7C, removal of the resist layers 310 and 320 completes the lead frame strip 10 in its final form. After removing the resist layers 310 and 320, a plating layer such as silver plating may be formed on the wire bonding portions of the leads 12.

### Second Embodiment

A second embodiment is directed to a semiconductor device manufactured using the lead frame strip 10 according to the first embodiment.

### [Semiconductor Device]

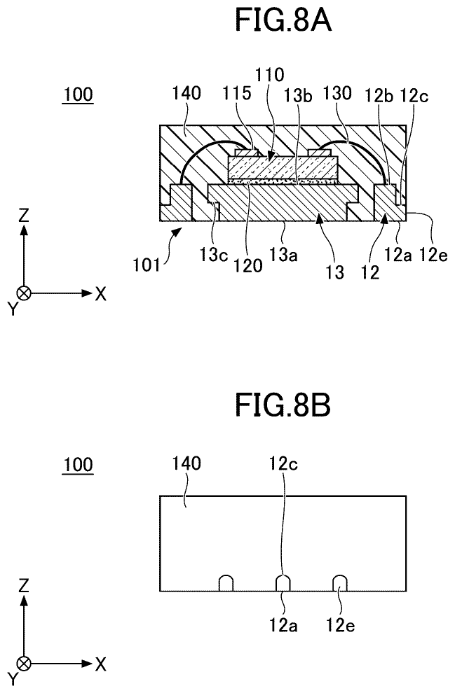

FIGS. 8A and 8B are drawings illustrating an example of a semiconductor device according to the second embodiment. FIG. 8A is a cross-sectional view and FIG. 8B is a side view.

As illustrated in FIGS. 8A and 8B, a semiconductor device 100 includes a lead frame 101, a semiconductor chip 110, an adhesive 120, metal wires 130 (i.e., bonding wires), and a resin portion 140. The semiconductor device 100 is a QFN (quad flat non-leaded package) type package.

The lead frame 101 is obtained by singulating the lead frame strip 10, and is a portion inside the distinct region R of the lead frame strip 10. The lead frame 101 includes leads 12, a die pad 13, and support bars 14. The lead frame 101 does not include the frame portion.

The semiconductor chip 110 is mounted on the upper surface 13b of the die pad 13 in a face-up state. The semiconductor chip 110 may be mounted (die-bonded) on the upper surface 13b of the die pad 13 using, for example, the adhesive 120 such as Ag paste. Electrode terminals 115 of the semiconductor chip 110 are electrically connected (wire-bonded) to the upper surfaces 12b of the leads 12 via the metal wires 130 such as gold wires or copper wires.

The resin portion 140 is provided on the lead frame 101. The resin portion 140 may be, for example, a mold resin obtained by mixing a filler in an epoxy resin. The resin portion 140 covers at least the semiconductor chip 110, the metal wires 130, the upper surfaces 12b of the leads 12, the side surfaces 12d of the leads 12, the step surfaces 12c of the leads 12, the upper surface 13b of the die pad 13, and the second step surface 13c of the die pad 13. As illustrated in FIG. 4B, the center of the side surface 12d of the lead 12 in the thickness direction bulges laterally further outward than the edges of the lower surface 12a and the upper surface 12b, resulting in an increase in the contact area with the resin portion 140. This arrangement effectively improves the adhesion between the leads 12 and the resin portion 140.

The resin portion 140 covers none of the lower surfaces 12a of the leads 12, the outer surfaces 12e of the leads 12, and the lower surface 13a of the die pad 13. The outer surfaces 12e of the leads 12 are cut surfaces of the leads 12 resulting from their separation from the frame portion 11. When viewed from the direction perpendicular to the outer surface 12e of each lead 12, the step surface 12c is convex upward, i.e., toward the plane of the upper surface. When viewed from the direction perpendicular to the outer surface 12e of each lead 12, the step surface 12c corresponds to an upper edge of the outer surface 12e.

Either the lower surfaces 12a or the outer surfaces 12e of the leads 12, or both may be used as external connection terminals, for example. The die pad 13 may be connected to the one or more ground terminals of the semiconductor chip 110 by one or more metal wires. This arrangement enables the die pad 13 to be used as a ground conductor.

### [Method of Making Semiconductor Device]

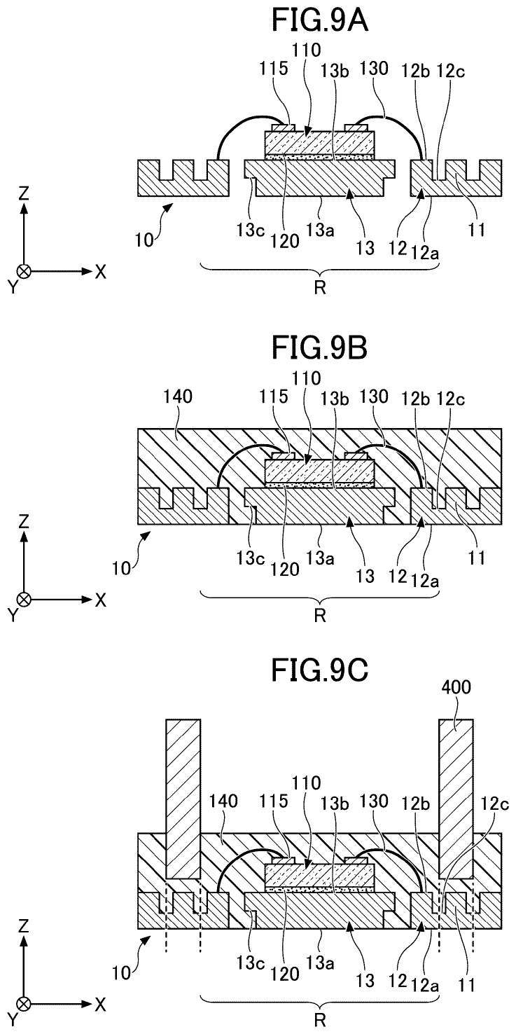

FIGS. 9A through 9C are drawings illustrating an example of the manufacturing process of the semiconductor device according to the second embodiment.

First, as illustrated in FIG. 9A, a semiconductor chip 110 is mounted on the upper surface 13b of the die pad 13 of each distinct region R of the lead frame strip 10 in a face-up state via the adhesive 120, and the adhesive 120 is cured by heating. This results in the semiconductor chip 110 being fixed to the upper surface 13b of the die pad 13. Further, the electrode terminals 115 formed on the upper surface of the semiconductor chip 110 are electrically connected to the upper surfaces 12b of the leads 12 via the metal wires 130 by wire bonding.

Next, as illustrated in FIG. 9B, the resin portion 140 for encapsulating the semiconductor chip 110 is formed. The resin portion 140 may be, for example, a mold resin obtained by mixing a filler in an epoxy resin. The resin portion 140 may be formed by, for example, a transfer molding method or a compression molding method.

Then, as illustrated in FIG. 9C, the structure illustrated in FIG. 9B is cut at the positions of the step surfaces 12c indicated by broken lines for singulation, thereby completing a plurality of semiconductor devices 100 in their final form. The cutting can be performed by, for example, using rotating blades 400. Since the positions of the step surfaces 12c are thinned by half-etching, cutting is easily done by the blade 400. Moreover, in the vertical cross-section taken through the step surfaces 12c and perpendicular to the direction in which the leads 12 extend, each step surface 12c is convex upward, i.e., toward the plane of the upper surface 12b, which reduces the contact area between the blade 400 and the step surface 12c, thereby reducing the risk of burring at the cut portion. As a result, the risk of a short circuit between adjacent leads 12 due to burring is effectively reduced. Moreover, reducing the contact area between the blade 400 and the step surface 12c diminishes the stress applied to the lead 12 at the time of cutting, which lowers the likelihood of separation between the lead 12 and the resin portion 140. This arrangement effectively improves the reliability of the semiconductor device 100.

### <First Variation>

A first variation is directed to examples of a lead frame strip without die pads and support bars, and a semiconductor device using the lead frame strip.

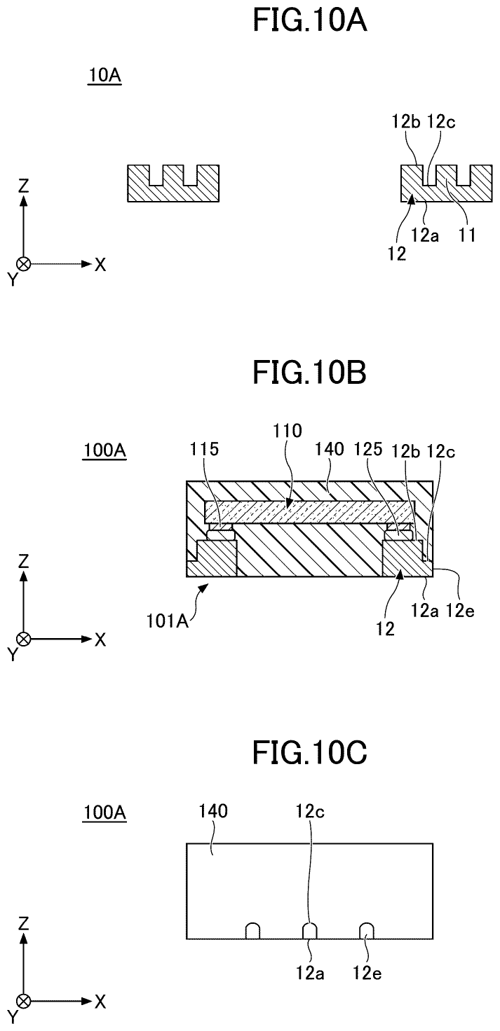

FIGS. 10A through 10C are drawings illustrating examples of a lead frame strip and a semiconductor device according to the first variation. FIG. 10A is a cross-sectional view of a lead frame strip. FIG. 10B is a cross-sectional view of a semiconductor device, and FIG. 10C is a side view of the semiconductor device.

A lead frame strip 10A illustrated in FIG. 10A differs from the lead frame strip 10 in that there are neither a die pad nor support bars. The shapes of the frame portion 11 and the leads 12 are the same as those of the lead frame strip 10.

A semiconductor device 100A illustrated in FIG. 10B includes a lead frame 101A, a semiconductor chip 110, bonding members 125, and a resin portion 140. The lead frame 101A is obtained by singulating the lead frame strip 10A, and is a portion inside a distinct region R of the lead frame strip 10A. The lead frame 101A includes the leads 12.

The semiconductor chip 110 is flip-chip mounted on the upper surfaces 12b of the leads 12 in a face-down state. The electrode terminals 115 of the semiconductor chip 110 are electrically connected to the upper surfaces 12b of the leads 12 via the bonding members 125 which are solder bumps or the like.

The resin portion 140 is provided on the lead frame 101A. The resin portion 140 covers at least the semiconductor chip 110, the bonding members 125, the upper surfaces 12b of the leads 12, the side surfaces 12d of the leads 12, and the step surfaces 12c of the leads 12. The resin portion 140 covers neither the lower surfaces 12a of the leads 12 nor the outer surfaces 12e of the leads 12. When viewed from the direction perpendicular to the outer surface 12e of each lead 12, the step surface 12c is convex upward, i.e., toward the plane of the upper surface. Either the lower surface 12a or the outer surface 12e of each lead 12, or both may be used, for example, as an external connection terminal.

As described above, the lead frame according to the present invention does not have to have either a die pad or support bars. Like the semiconductor device 100, the semiconductor device 100A is configured such that each step surface 12c is convex upward, i.e., toward the plane of the upper surface, which makes it unlikely for burring to occur on the cut surfaces of the leads 12, and, thus, a short circuit is unlikely to occur between adjacent leads 12. Also, as in the semiconductor device 100, separation between the leads 12 and the resin portion 140 is unlikely to occur. This arrangement effectively improves the reliability of the semiconductor device 100A.

### <Second Variation>

A second variation is directed to an example in which a recess is provided in a frame portion at a position between adjacent leads in the top view.

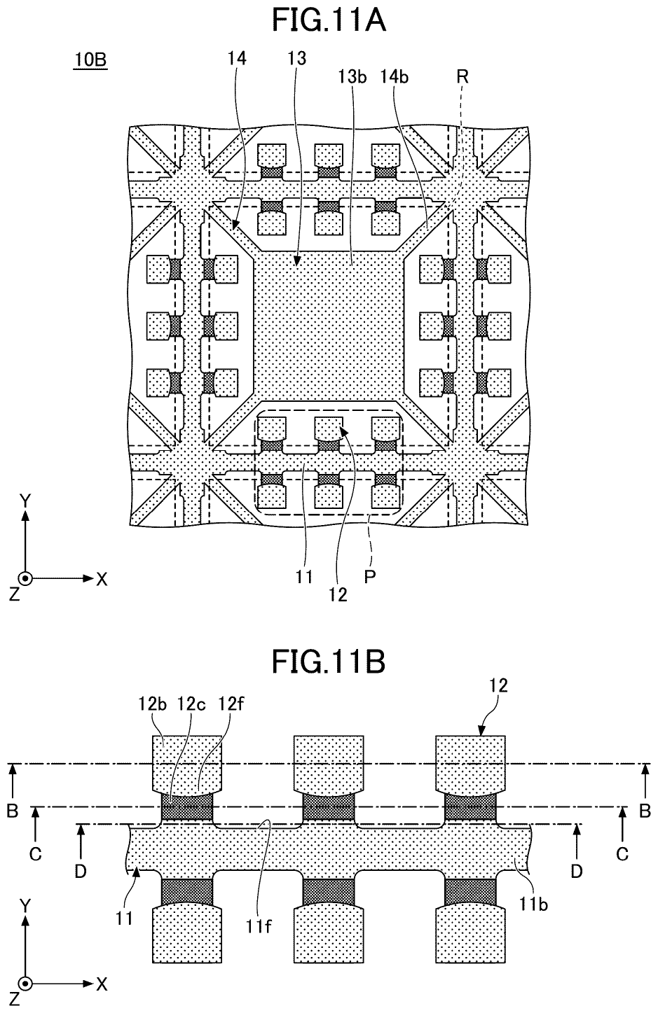

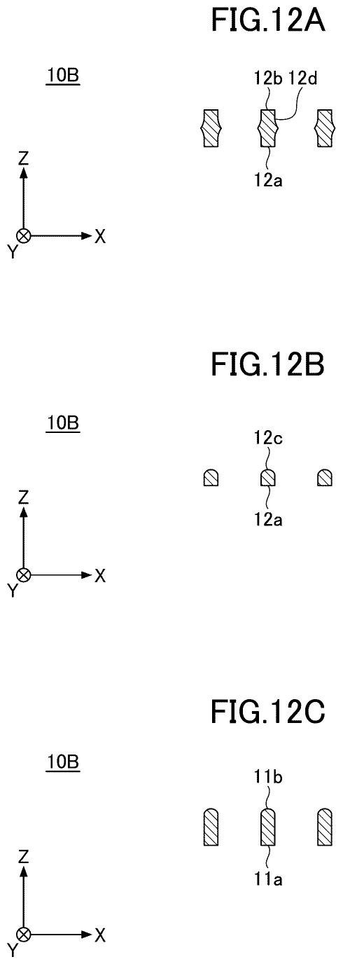

FIGS. 11A and 11B are top views illustrating an example of a distinct region and its surrounding area of a lead frame strip according to the second variation. FIG. 11A illustrates the entire distinct region, and FIG. 11B illustrates an enlarged view of a portion P illustrated in FIG. 11A. FIGS. 12A through 12C are cross-sectional views illustrating the example of the distinct region and its surrounding area of the lead frame strip according to the second variation. FIG. 12A illustrates the cross-section along the line B-B in FIG. 11B. FIG. 12B illustrates the cross-section along the line C-C in FIG. 11B. FIG. 12C illustrates the cross-section along the line D-D in FIG. 11B.

As illustrated in FIGS. 11A and 11B and FIGS. 12A through 12C, a lead frame strip 10B is such that, in the top view, each lead 12 has a convex portion 12f projecting toward the step surface 12c. In the top view, the edge of the convex portion 12f toward the step surface 12c is curved in a round shape. In the lead frame strip 10B, the width of the step surface 12c is narrower than the width of the upper surface 12b. In the top view, the portion of the frame portion 11 positioned at the junction with each lead 12 has a straight edge toward the step surface 12c. In the top view, the frame portion 11 has a recessed portion 11f, between adjacent leads 12, set back in a direction opposite to the direction in which the leads 12 project. Both ends of the recessed portion 11f in the X-axis direction are, for example, rounded.

The cross-sectional shape illustrated in FIG. 12A is the same as the cross-sectional shape illustrated in FIG. 4B. The cross-sectional shape illustrated in FIG. 12B is the same as the cross-sectional shape illustrated in FIG. 4C. In the cross-sectional shape illustrated in FIG. 12C, the lower surfaces 11a of the frame portion 11 is flat. The upper surfaces 11b of the frame portion 11 located on both sides of the recessed portion 11f are each convex toward the direction away from the lower surfaces 11a. Each of the upper surfaces 11b of the frame portion 11 located on both sides of the recessed portion 11f is, for example, a rounded shape in which the height is highest at the center in the X-axis direction and gradually decreases toward the periphery from the center in the X-axis direction.

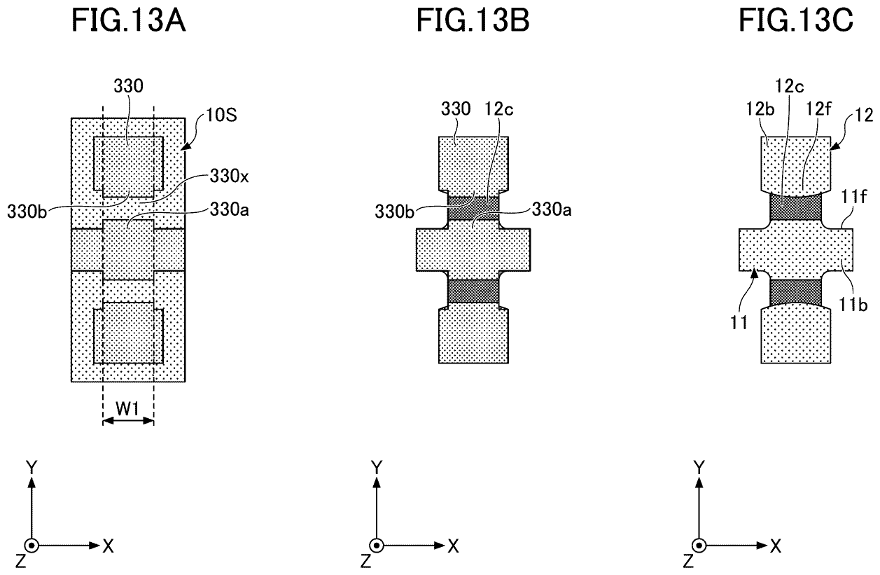

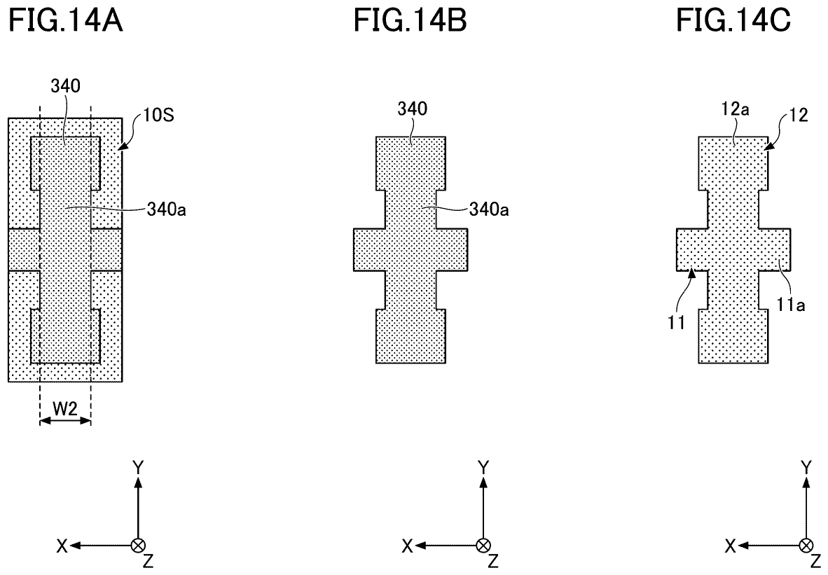

FIGS. 13A through 13C are top views illustrating an example of a method of making the shape illustrated in FIG. 11B. FIGS. 14A through 14C are bottom views illustrating the example of the method of making the shape illustrated in FIG. 11B.

In order to fabricate the shape illustrated in FIG. 11B, as illustrated in FIGS. 13A and 14A, resist layers 330 and 340 are formed on the upper surface and the lower surface of the plate 10S, respectively. The resist layer 330 has an opening 330x that exposes a region for forming the step surface 12c, and has projections 330a and 330b that face each other across the opening 330x. The resist layer 340 has a covering portion 340a that covers the area overlapping the opening 330x in plan view. The widths W1 of each of the projections 330a and 330b of the resist layer 330 is equal to the width W2 of the covering portion 340a of the resist layer 340.

Next, as illustrated in FIGS. 13B and 14B, the plate 10S is etched using the resist layers 330 and 340 as etching masks. Then, as illustrated in FIGS. 13C and 14C, the resist layers 330 and 340 are removed, and the fabrication of the shape illustrated in FIG. 11B is completed. Recessed portions 11f are formed on both sides of the projection 330a in the X-axis direction. Further, a convex portion 12f is formed at the position corresponding to the projection 330b.

As described above, since the frame portion 11 has the recessed portions 11f between adjacent leads 12 set back in the direction opposite to the direction in which the leads 12 project in the top view, generation of side edges between the adjacent leads 12 is effectively suppressed. The presence of side edges increases the contact area between a blade and a step surface at the time of cutting the plate, which increases the likelihood of burring. In contrast, suppressing the generation of side edges reduces the likelihood of burring between the adjacent leads 12.

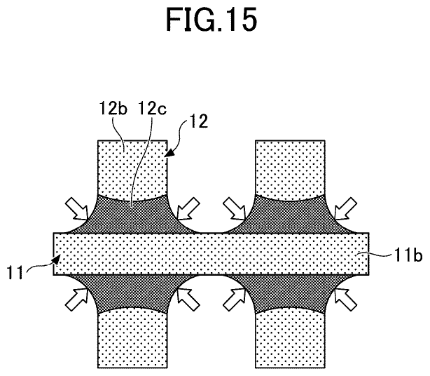

The “side edge” between adjacent leads 12 refer to a curved shape like a hill slope that is formed when etching is insufficient between the adjacent leads 12, as indicated by arrows in FIG. 15.

### <Third Variation>

A third variation is directed to an example in which the frame portion has convex portions at the junctions with the leads in the top view.

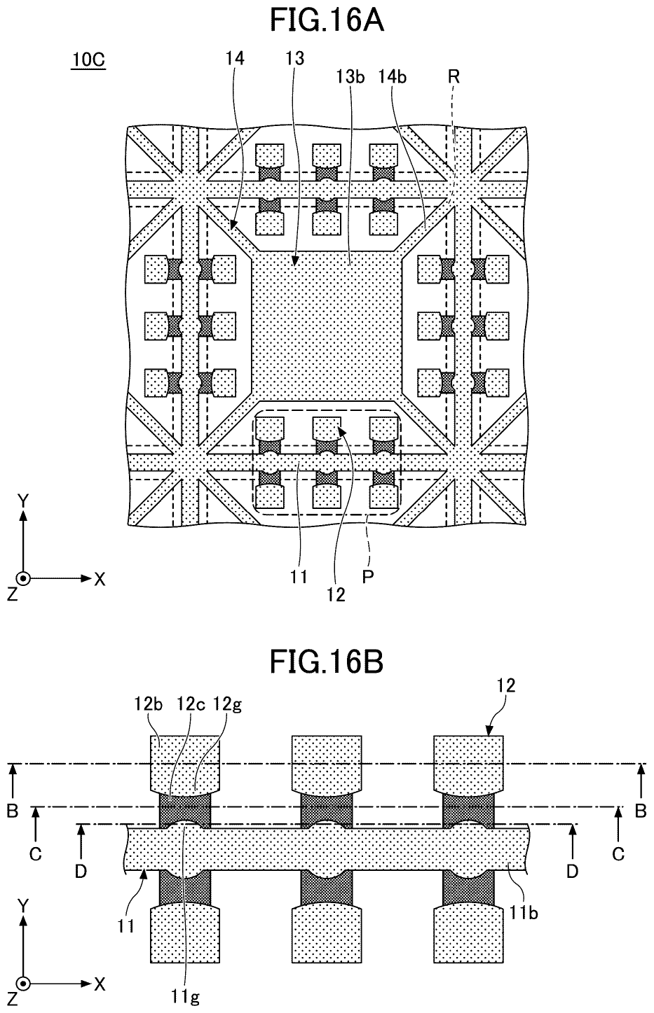

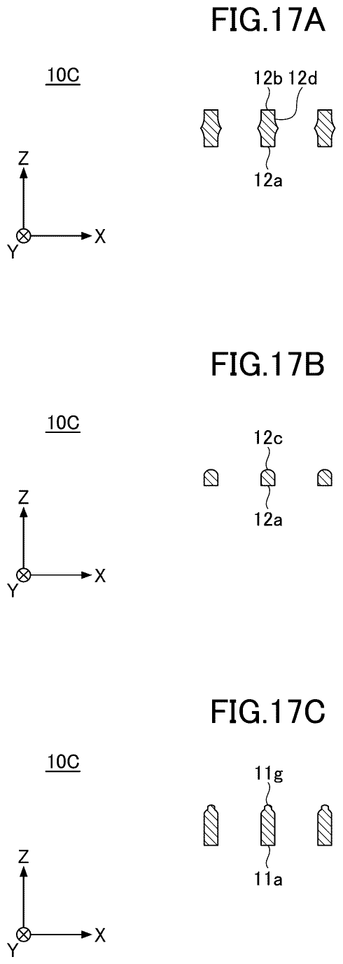

FIGS. 16A and 16B are top views illustrating an example of a distinct region and its surrounding area of a lead frame strip according to the third variation. FIG. 16A illustrates the entire distinct region, and FIG. 16B illustrates an enlarged view of a portion P illustrated in FIG. 16A. FIGS. 17A through 17C are cross-sectional views illustrating the example of the distinct region and its surrounding area of the lead frame strip according to the third variation, and FIG. 17A illustrates the cross-section along the line B-B illustrated in FIG. 16B. FIG. 17B illustrates the cross-section along the line C-C illustrated in FIG. 16B, and FIG. 17C illustrates the cross-section along the line D-D illustrated in FIG. 16B.

As illustrated in FIGS. 16A and 16B and FIGS. 17A through 17C, the lead frame strip 10C is such that, in the top view, each lead 12 has a convex portion 12g projecting toward the step surface 12c. In the top view, the edge of the convex portion 12g toward the step surface 12c is curved in a round shape. In the lead frame strip 10C, the width of the step surface 12c is narrower than the width of the upper surface 12b.

In the top view, the frame portion 11 has convex portions 11g projecting in the direction in which the leads 12 project at the junctions with the leads 12. That is, in the top view, each convex portion 11g is provided at the position opposite the corresponding convex portion 12g across the step surface 12c. In the top view, the edge of each convex portion 11g toward the step surface 12c is curved in a round shape. The frame portion 11 may have straight edges on both sides of the convex portion 11g at the junction with the lead 12.

The cross-sectional shape illustrated in FIG. 17A is the same as the cross-sectional shape illustrated in FIG. 4B. The cross-sectional shape illustrated in FIG. 17B is the same as the cross-sectional shape illustrated in FIG. 4C. In the cross-sectional shape illustrated in FIG. 17C, the lower surface 11a of the frame portion 11 is flat. The upper surface of each convex portion 11g is convex toward the direction away from the lower surface 11a. The upper surface of the convex portion 11g has, for example, a shape in which the central portion in the X-axis direction is highest and the height gradually decreases toward the periphery from the central portion in the X-axis direction. The shape is a round curved shape. The upper surface of the convex portion 11g may have a shape including a first curved portion curved across the entire width and a second curved portion projecting from the center area of the first curved portion.

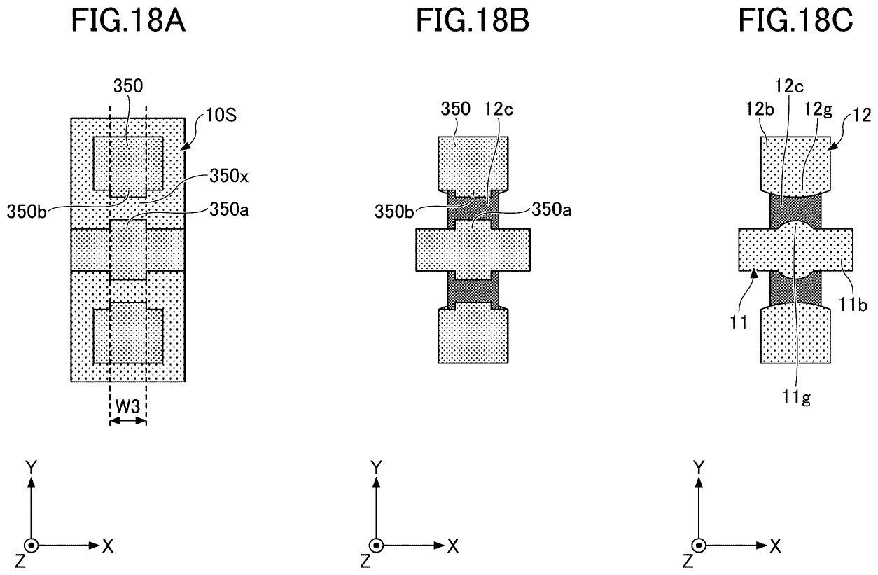

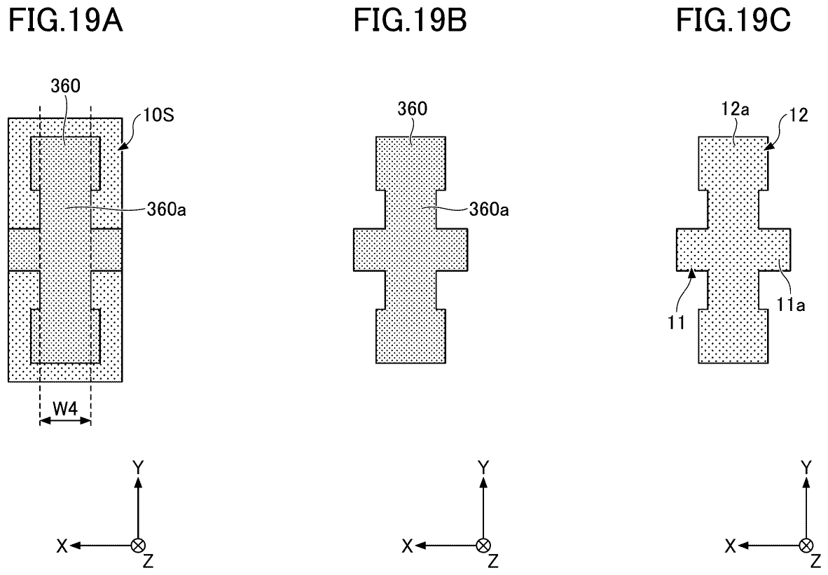

FIGS. through 18A 18C are top views illustrating an example of a method of making the shape illustrated in FIG. 16B. FIGS. 19A through 19C are bottom views illustrating the example of the method of making the shape illustrated in FIG. 16B. To fabricate the shape illustrated in FIG. 16B, first, as illustrated in FIGS. 18A and 19B, resist layers 350 and 360 are formed on the upper surface and the lower surface of the plate 10S, respectively. The resist layer 350 has an opening 350x that exposes a region for forming the step surface 12c, and has projections 350a and 350b that face each other across the opening 350x. The resist layer 360 has a covering portion 360a that covers the area overlapping the opening 350x in plan view. The width W3 of each of the projections 350a and 350b of the resist layer 350 is narrower than the width W4 of the covering portion 360a of the resist layer 360.

Next, as illustrated in FIGS. 18B and 19B, the plate 10S is etched using the resist layers 350 and 360 as etching masks. Then, as illustrated in FIGS. 18C and 19C, the resist layers 350 and 360 are removed, and the fabrication of the shape illustrated in FIG. 16B is completed. The convex portions 11g and 12g are formed at positions corresponding to the projections 350a and 350b, respectively.

As described above, since the frame portion 11 has the convex portions 11g projecting in the direction in which the leads 12 projects at the junctions with the leads 12 in the top generation of side edges between adjacent leads 12 is effectively suppressed. As previously described, side edges may serve to cause barring. Suppressing the generation of side edges reduces the likelihood of burring between adjacent leads 12.

According to at least one embodiment, a lead frame strip has a structure that is unlikely to cause a short circuit between adjacent leads.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

The disclosures herein non-exclusively contain the subject matter as set out in the following clause.

Clause 1. A method of making a lead frame strip, comprising:
providing a first resist layer and a second resist layer on an upper surface and a lower surface, respectively, of a metal plate; and
etching the metal plate through the first resist layer and the second resist layer to form a frame portion and a plurality of leads projecting from an inner edge of the frame portion to an inside of the frame portion, the plurality of leads having a lower surface, an upper surface opposite the lower surface, and a step surface recessed relative to the upper surface toward the lower surface,
wherein the providing e first resist layer and the second resist layer includes forming a region where only the second resist layer exists, without the first resist layer, in plan view, and
wherein the etching the metal plate includes half-etching the region from the upper surface to form the step surface, causing the step surface to become convex upward in a vertical cross-section taken through step the surface perpendicularly to a direction in which the leads project.

What is claimed is:

1. A lead frame strip comprising:
a frame portion; and
a plurality of leads projecting from an inner edge of the frame portion to an inside of the frame portion;
wherein each of the leads has:
a lower surface;
an upper surface opposite the lower surface; and
a step surface recessed relative to the upper surface toward the lower surface, and
wherein the step surface is convex upward in a vertical cross-section that is taken through the step surface perpendicularly to a direction in which the leads project.

2. The lead frame strip according to claim 1, wherein the step surface is parallel to the lower surface in a vertical cross-section that is taken through the step surface, parallel to the direction in which the leads project.

3. The lead frame strip according to claim 1, wherein, in a vertical cross-section passing through the lower surface and the upper surface and perpendicular to the direction in which the leads project, a side surface connecting the lower surface and the upper surface has a center portion in a thickness direction bulging laterally further outward than edges of the lower surface and the upper surface.

4. The lead frame strip according to claim 1, wherein a width of the step surface is equal to a width of the upper surface.

5. The lead frame strip according to claim 1, wherein in a top view, the frame portion has a recessed portion set back between adjacent ones of the leads toward a direction opposite to the direction in which the leads project.

6. The lead frame strip according to claim 1, wherein in a top view, the frame portion has convex portions projecting in the direction in which the leads project at junctions with the leads.

7. The lead frame strip according to claim 5, wherein a width of the step surface is narrower than a width of the upper surface.

8. The lead frame strip according to claim 1, wherein an upper surface of the frame portion is flush with the upper surface of each of the leads, and a lower surface of the frame portion is flush with the lower surface of each of the leads.

9. A semiconductor device comprising:
a plurality of leads each having a lower surface, an upper surface opposite the lower surface, a step surface recessed relative to the upper surface toward the lower surface, and an outer surface connecting the lower surface and the step surface;
a semiconductor chip electrically connected to the leads; and
a resin portion covering the semiconductor chip, the upper surface, and the step surface and covering neither the lower surface nor the outer surface,
wherein the step surface is convex upward when viewed from a direction perpendicular to the outer surface.
